(19) United States
(12) Patent Application Publication
(10) Pub. No.: US 2003/0088816 A1
(43) Pub. Date: May 8, 2003

(54) Method and system for detecting and isolating faulted part of a memory device

(76) Inventors: Kun-Ho Wu, Feng-Shan (TW); Hai-Feng Chuang, Tainan (TW)

Correspondence Address: J.C. Patents, Inc., Suite 250, 4 Venture, Irvine, CA, 92618, US

(21) Appl. No.: 10/005,929

(22) Filed: Nov. 8, 2001

(51) Int. Cl. H04B 1/74; H04L 1/22; H02H 3/05; H05K 10/00; H03K 19/003; G11C 29/00

(52) U.S. Cl. 714/723; 714/42

(57) ABSTRACT

A memory fault detection and isolation system method is proposed, which is designed for use on a memory device to isolate any faulted part of the memory device from being accessible. The proposed memory fault detection and isolation system method is characterized by the use of a decoding unit coupled between the access-control unit and the memory device to perform a row-address inversion mode to invert the row address of a faulted part of the memory device to the bottom half portion of the current memory scan range. Subsequently, the memory scan range is reduced to the bottom half portion to repeat a new memory scan until the remaining memory range reaches the minimum isolatable range so that the faulted part can be isolated from being accessible. This allows the memory device to be nevertheless usable in the event of the occurrence of a faulted part for effective use of the memory device.

### BACKGROUND OF THE INVENTION

1. Field of the Invention

This invention relates to computer memory technology, and more particularly, to a method and system for detecting and isolating a faulted part of a memory device.

2. Description of Related Art

Memory is an indispensable component in computers and intelligent electronic devices for storing program code and data. During operation, however, a memory device may contain a faulted part which is no longer usable for data storage. The faulted part may even cause the entire computer system to shut down if critical system data are stored therein. By conventional technology, computer system can detect faulted part of the memory device and generate a warning message to the user. However, it may nevertheless cause the system to shut down since the faulted part of the memory device is still unusable.

### SUMMARY OF THE INVENTION

It is therefore an objective of this invention to provide a method and system for detecting and isolating faulted part(s) of a memory device, which allows a memory device to be nevertheless usable for data storage when it contains a faulted part by isolating the faulted part and relocating the data in the faulted part to other locations of the memory device.

The memory fault detection and isolation system according to the invention is designed for use on a memory device to isolate any faulted part of the memory device from being accessible, and which comprises an access-control unit, a mode-setting storage unit, a decoding unit, and a firmware-based memory scanning unit. The access-control unit is capable of generating a primitive set of address and chip selection signals for controlling access to the memory device. The mode-setting storage unit is sued for storing the setting of a selected operation mode that allows the decoding unit to isolate the faulted part of the memory device. The decoding unit is coupled to the access-control unit, the mode-setting storage unit, and the memory device for converting the primitive set of address and chip selection signals into an output set of address and chip selection signals based on the current setting of operation mode stored in the mode-setting storage unit; and the firm ware-based memory scanning unit is coupled to the access-control unit for controlling the access-control unit to scan the memory device which detects any faulted part of the memory device, and which is capable of selecting a suitable operation mode for the decoding unit and storing the setting of the selected operation mode into the mode-setting storage unit to thereby allow the decoding unit to perform under the operation mode to isolate the faulted part of the memory device from being accessible. In the access control operation, the primitive set of address and chip selection signals include: a first bank-address signal, a second bank-address signal, a column-address signal, a row-address signal, a first chip-selection signal, and a second chip-selection signal. The output set of address and chip selection signals include: an output bank-address signal, an output column-address signal, an output row-address signal, an output first chip-selection signal, and an output second chip-selection signal.

In the memory fault detection and isolation system according to the invention, the decoding unit includes two operation modes: a direct-forward mode and a row-address inversion mode wherein the direct-forward mode is used to forward the primitive set of address and chip selection signals directly as the output set of address and chip selection signals to the memory device and the row-address inversion mode is used to invert the row-address signal in the primitive set of address and chip selection signals to an inverted row-address signal so as to relocate the faulted part to the bottom half portion of the current memory scan range.

In the preferred embodiment of the invention, the decoding unit further includes the following operation modes: a chip-slicing mode, a faulted-chip slicing mode, a chip-combining mode, a faulted-chip bank-address slicing mode, a bank chip combining mode, and a chip bank-address slicing mode. The chip-slicing mode is used to slice the storage space of the memory device by simulation into a plurality of subregions. The faulted-chip slicing mode is used to slice the faulted part of the memory device based on its row address and isolate the faulted part from being accessible so as to obtain a new chip that is half in capacity but has the same number of banks. The chip-combining mode is used to combine two or more isolated faulted parts into a single chip by simulation. The faulted-chip bank-address slicing mode is used to slice the faulted part of the memory device in banks. The bank chip combining mode is used to combine a plurality of faulted parts which have been isolated in banks into an integral chip. The chip bank-address slicing mode is used to slice each of the isolated faulted parts which have been isolated in banks further into a plurality of subbanks.

The memory fault detection and isolation method according to the invention is proposed for use on a memory system including a memory device, an access-control unit, a decoding unit, and a mode-setting storage unit, for isolating any faulted part of the memory device from being accessible. The method, according to the invention, comprises the steps of: initiating an auto fault detection mode; setting the decoding unit to a direct-forward mode to detect all of the memory space of the memory device; scanning all the memory space of the memory device to find if it contains a fault part. In the event that the memory device contains a faulted part, finding the distribution of the faulted part to thereby set the decoding unit to a selected operation mode; storing the setting of the selected operation mode into the mode-setting storage unit; and if the auto fault detection mode is not initiated, fetching the current setting of operation mode stored in the mode-setting storage unit; and reporting the usable memory capacity in the memory device based on the current setting of operation mode.

In the preferred embodiment of the invention, in order to allow the faulted part to be relocated to the bottom half portion of the current memory scan range so that the faulted part can be isolated within the minimum isolatable range, the method of the invention further comprises the substeps of: in the event of the memory device containing a faulted part, checking whether the faulted part is located within the upper half portion of the current memory scan range. If yes, then setting the decoding unit to a row-address inversion mode to invert the row address of the faulted part to the bottom half portion of the current memory scan range; checking whether the current memory scan range has reached the minimum isolatable range of the memory device. If no, then adjusting for a new memory scan range to the bottom half portion of the current memory scan range and scanning the newly-adjusted memory scan range for any faulted part.

In conclusion, this invention provides a memory fault detection and isolation system and method that is characterized by the use of a decoding unit coupled between the access-control unit and the memory device to perform a row-address inversion mode to invert the row address of a faulted part of the memory device to the bottom half portion of the current memory scan range, and subsequently the memory scan range is reduced to the bottom half portion to repeat a new memory scan until the remaining memory range reaches the minimum isolatable range so that the faulted part can be isolated from being accessible. This allows the memory device to be nevertheless usable in the event of the occurrence of a faulted part.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing the architecture of the memory fault detection and isolation system according to the invention; and

FIG. 2 is a flow diagram showing the procedural steps involved in the method according to the invention for detecting and isolating faulted part of a memory device.

### DETAILED DESCRIPTION OF PREFERRED EMBODIMENTS

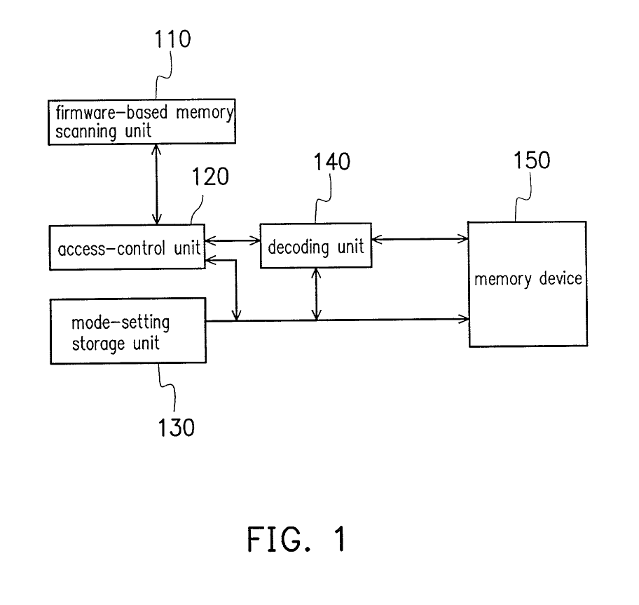

FIG. 1 is a schematic diagram showing the architecture of the memory fault detection and isolation system according to the invention. As shown, the memory fault detection and isolation system according to the invention is designed for use with a memory device 150 for isolating any faulted part of the memory device 150, and which comprises a firmware-based memory scanning unit 110, an access-control unit 120, a mode-setting storage unit 130, and a decoding unit 140. The memory device 150 is used for storing program codes and data. The access-control unit 120 is used to control all access operations on the memory device 150 by issuing a primitive set of address and chip selection signals. The mode-setting storage unit 130 is preferably an EEPROM unit which is used to store the setting of an optimal operation mode for the decoding unit 140 to isolate the faulted part of the memory device 150. The decoding unit 140 is coupled to the access-control unit 120, the mode-setting storage unit 130, and the memory device 150 for decoding the primitive set of address and chip selection signals from the access-control unit 120 into an output set of address and chip selection signals based on the current setting of operation mode stored in the mode-setting storage unit 130 which can transfer the output set of address and chip selection signals to the memory device 150 for access control to the memory device 150. The firmware based memory scanning unit 110 is coupled to the access-control unit 120 and is capable of scanning the memory device 150 for any faulted part and selects a suitable operation mode for the decoding unit 140 based on the distribution of faulted part in the memory device 150. The firmware based memory scanning unit 110 further stores the setting of the selected operation mode into the mode-setting storage unit 130. In the access control operation, the primitive set of address and chip selection signals include: a first bank-address signal, a second bank-address signal, a column-address signal, a row-address signal, a first chip-selection signal, and a second chip-selection signal. The output set of address and chip selection signals include: an output bank-address signal, an output column-address signal, an output row-address signal, an output first chip-selection signal, and an output second chip-selection signal.

As shown in FIG. 1, the decoding unit 140 includes two operation modes: a direct-forward mode and a row-address inversion mode; wherein the direct-forward mode is used to forward the primitive set of address and chip selection signals directly to the memory device 150 without undergoing a decoding process to gain access to the memory device 150; while the row-address inversion mode is used to invert the primitive column-address signal into the output column-address signal.

In addition, the decoding unit 140 further includes the following operation modes: a chip-slicing mode, a faulted-chip slicing mode, a chip-combining mode, a faulted-chip bank-address slicing mode, a bank chip combining mode, and a chip bank-address slicing mode.

The chip-slicing mode is used to slice the storage space of the memory device 150 by simulation into a plurality of subregions, wherein when the first chip-selection signal or the second chip-selection signal is enabled, it enables the output first chip-selection signal; and when the first chip-selection signal is enabled while the second chip-selection signal is disabled, it causes the most significant bit in the output row-address signal to be set to logic-LOW; and when the first chip-selection signal is disabled while the second chip-selection signal is enabled, it causes the most significant bit in the output row-address signal to be set to logic-HIGH.

The faultedchip slicing mode is used to slice the faulted part of the memory device 150 and isolate the faulted part from being accessible. Under this mode, the most significant bit of the output row-address signal is fixedly set at either logic-HIGH or logic-LOW.

The chipcombining mode is used to combine two or more isolated faulted parts into a single chip by simulation. Under this mode, the first chip-selection signal is enabled while the most significant bit of the row-address signal is at logic-LOW, this causes the output first chip-selection signal to be enabled; and when the first chip-selection signal is enabled while the most significant bit of the row-address signal is at logic-HIGH, it causes the second output chip-selection signal to be enabled.

The faulted-chip bank-address slicing mode is used to slice the faulted part of the memory device 150 in banks. Under this mode, the most significant bit of the output bank-address signal is set to either logic-HIGH or logic-LOW.

The bank chip combining mode is used to combine a plurality of faulted parts which have been isolated in banks into an integral chip. Under this mode, when the first chip-selection signal is enabled while the first bank-address signal and the second bank-address signal are at logic-LOW, it causes the output first chip-selection signal and the output bank-address signal to be set to logic-LOW; when the first chip-selection signal is enabled while the first bank-address signal is at logic-LOW and the second bank-address signal is at logic-HIGH, it causes the output first chip-selection signal to be enabled and the output bank-address signal to be set to logic-HIGH; when the first chip-selection signal is enabled while the first bank-address signal is at logic-HIGH and the second bank-address signal is at logic-LOW, it causes the second output chip-selection signal to be enabled and the output bank-address signal to be set to logic-LOW; and when the first chip-selection signal is enabled while the first bank-address signal is at logic-HIGH and the second bank-address signal is also at logic-HIGH, it causes the second output chip-selection signal to be enabled and the output bank-address signal to be set to logic-HIGH.

The chip bank-address slicing mode is used to slice each of the isolated faulted parts which have been isolated in banks further into a plurality of subbanks. Under this mode, when the first bank-address signal and the second bank-address signal are both at logic-LOW, it causes the output bank-address signal to be set to logic-LOW and the most significant bit of the output row-address signal to be set to logic-LOW; when the first bank-address signal is at logic-LOW and the second bank-address signal is at logic-HIGH, it causes the output bank-address signal to be set to logic-LOW and the most significant bit of the output row-address signal to be set to logic-HIGH; when the first bank-address signal is at logic-HIGH and the second bank-address signal is at logic-LOW, it causes the output bank-address signal to be set to logic-HIGH and the most significant bit of the output row-address signal to be set to logic-LOW; and when the first bank-address signal is at logic-HIGH while the second bank-address signal is also at logic-HIGH, it causes the output bank-address signal to be set to logic-HIGH and the most significant bit of the output row-address signal to be set to logic-HIGH.

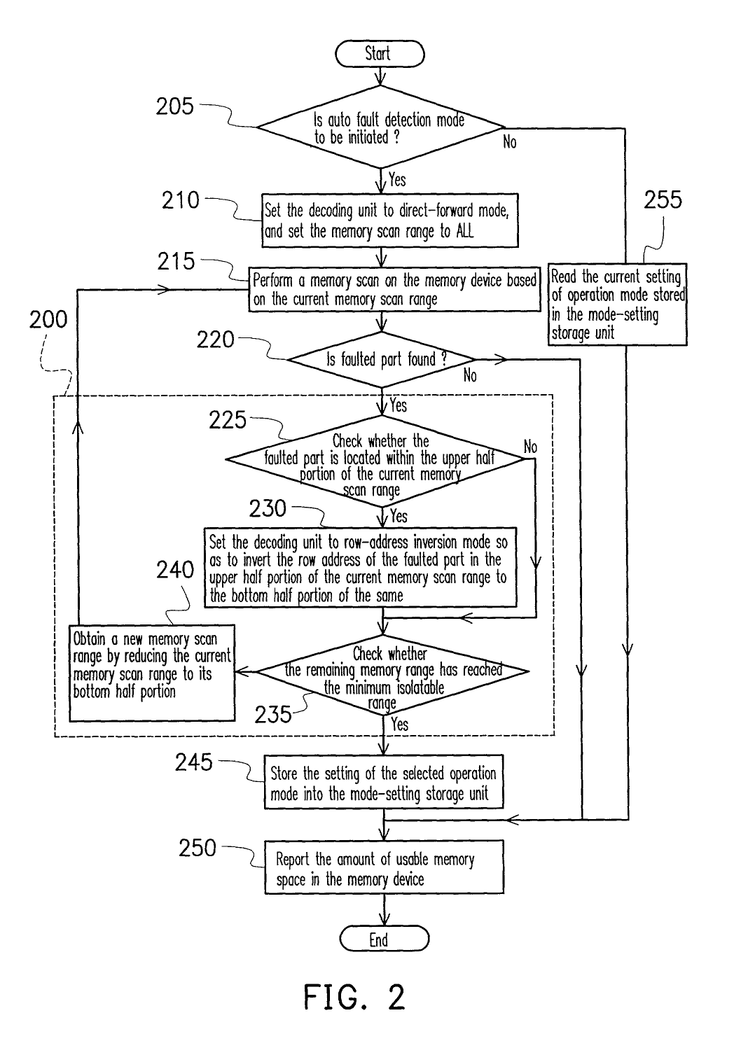

FIG. 2 is a flow diagram showing the procedural steps involved in the method according to the invention for detecting and isolating faulted part of a memory device.

As shown, in the initial step 205, it is judged whether to initiate an auto fault detection mode; if YES, the procedure goes to the step 210; and whereas if NO, the procedure goes to the step 255.

In the step 210, the decoding unit 140 is set to the direct-forward mode, and the memory scan range is set to ALL (all of the storage space of the memory device 150). The procedure then goes to the step 215, in which a memory scan is performed on the memory device 150 based on the current memory scan range; and in the step 220 it is checked whether the memory device 150 contains a faulted part; if YES, the procedure goes to the step 220 (which includes a number of substeps 225, 230, 235, and 250); and whereas if NO, the procedure goes to the step 250. The purpose of the step 220 is to find the distribution of the faulted part to thereby set the decoding unit 140 to a suitable operation mode that can optimally isolate the faulted part. In the step 245, the setting of the selected operation mode is stored into the mode-setting storage unit 130. In the step 255 (i.e., in the case that auto fault detection mode is not selected in step 205), the current setting of operation mode is read from the mode-setting storage unit 130; and then in the step 250, the amount of usable memory space in the memory device 150 is reported.

In the step 225, it is checked that whether the faulted part is located within the upper half portion of the current memory scan range; if YES, the procedure goes to the step 230; and whereas if NO, the procedure goes to the step 235. In the step 230, the decoding unit 140 is set to the row-address inversion mode to invert the row address of the faulted part in the upper half portion of the current memory scan range to the bottom half portion of the same. The procedure then goes to the step 235, in which it is checked whether the remaining memory range has reached the minimum isolatable range; if YES, the procedure goes to the step 245; and whereas if NO, the procedure goes to the step 240. In the step 240, a new memory scan range is obtained by reducing the current memory scan range to its bottom half portion; and then the procedure returns to the step 215 to repeat a memory scan on the memory device 150 within the newly-adjusted range.

Assume the memory device 150 has a capacity of 8 MB (megabyte) arranged in rows R0-R12 and columns C0-C9 and a minimum isolatable range of 1 MB, and further assume that every first byte at address 0 is faulted. By the invention, the first step is to initiate the auto fault detection mode, and then set the decoding unit 140 to the direct-forward mode with the memory scan range being set to the entire memory space 8 MB. The memory device 150 is then scanned to find any faulted part. Since every first byte at address 0 is faulted, the decoding unit 140 is then set to the row-address inversion mode to invert R12, so as to relocate the faulted first byte to the first address location in the 4MB bottom half portion of the current memory scan range. After this, since 4 MB>1 MB, the next memory scan is directed to the 4 MB bottom half portion of the entire memory space. Since the first byte at address 0 is faulted, the decoding unit 140 is then set to the row-address inversion mode to invert R12 and R11, so as to relocate the faulted first byte within this 4 MB memory range to the first address location in the 2 MB bottom half portion of the current memory scan range. After this, it is checked that 2 MB>1 MB, and therefore the memory scan continues to the subsequent 2 MB of memory space. Since the first byte at address 0 within the subsequent 2 MB is faulted, the decoding unit 140 is then set to perform the row-address inversion mode to invert R12, R11, and R10, so as to relocate the faulted first byte within this 2 MB range to the first address location in the 1 MB bottom half portion of the current memory scan range. At this time, since the minimum isolatable range 1 MB has been reached, the current setting of operation mode is stored into the mode-setting storage unit 130. It is then reported that the usable memory space is 7 MB, and the 1 MB faulted part is isolated from use.

In conclusion, this invention provides a memory fault detection and isolation system method that is characterized by the use of a decoding unit coupled between the access-control unit and the memory device to perform a row-address inversion mode to invert the row address of a faulted part of the memory device to the bottom half portion of the current memory scan range. Subsequently, the memory scan range is reduced to the bottom half portion to repeat a new memory scan until the remaining memory range reaches the minimum isolatable range, so that the faulted part can be isolated from being accessible. This allows the memory device to be usable in the event of the occurrence of a faulted part.

This invention has been described using exemplary preferred embodiments. However, it is to be understood that the scope of the invention is not limited to the above disclosed embodiments. This invention is intended to cover various modifications and similar arrangements. The scope of the claims, therefore, should be accorded the broadest interpretation so as to encompass all such modifications and/or other similar arrangements.

What is claimed is:

1. A memory fault detection and isolation method for use on a memory system including a memory device, an access-control unit, a decoding unit, and a mode-setting storage unit, for isolating any faulted part of the memory device from being accessible;
the memory fault detection and isolation method comprising the steps of:
(1) initiating an auto fault detection mode;
(2) setting the decoding unit to a direct-forward mode to detect all of the memory space of the memory device;
(3) scanning all the memory space of the memory device to find if it contains a fault part;
(4) in the event that the memory device contains a faulted part, finding the distribution of the faulted part to thereby set the decoding unit to a selected operation mode;
(5) storing the setting of the selected operation mode into the mode-setting storage unit;
(6) if the auto fault detection mode is not initiated, fetching the current setting of operation mode stored in the mode-setting storage unit, and;
(7) reporting the usable memory capacity in the memory device based on the current setting of operation mode.

2. The method of claim 1, wherein said step (4) comprises the substeps of:
in the event of the memory device containing a faulted part, checking whether the faulted part is located within the upper half portion of the current memory scan range;
if YES, setting the decoding unit to a row-address inversion mode to invert the row address of the faulted part to the bottom half portion of the current memory scan range;
checking whether the current memory scan range has reached the minimum isolatable range of the memory device;
if NO, adjusting for a new memory scan range to the bottom half portion of the current memory scan range;
scanning the newly-adjusted memory scan range for any faulted part.

3. A memory fault detection and isolation system for use on a memory device to isolate any faulted part of the memory device from being accessible;
the memory fault detection and isolation system comprising of:
an access-control unit, which is capable of generating a primitive set of address and chip selection signals for controlling access to the memory device;
a mode-setting storage unit for storing the setting of a selected operation mode that allows the decoding unit to isolate the faulted part of the memory device;
a decoding unit coupled to the access-control unit, the mode-setting storage unit, and the memory device, for converting the primitive set of address and chip selection signals into an output set of address and chip selection signals based on the current setting of operation mode stored in the mode-setting storage unit; and;
a firmware-based memory scanning unit, which is coupled to the access-control unit for controlling the access-control unit to scan the memory device to thereby detect any faulted part of the memory device, and which is capable of selecting a suitable operation mode for the decoding unit and storing the setting of the selected operation mode into the mode-setting storage unit to thereby allow the decoding unit to perform under the operation mode to isolate the faulted part of the memory device from being accessible.

4. The memory fault detection and isolation system of claim 3, wherein the primitive set of address and chip selection signals include: a first bank-address signal, a second bank-address signal, a column-address signal, a row-address signal, a first chip-selection signal, and a second chip-selection signal.

5. The memory fault detection and isolation system of claim 4, wherein the decoding unit includes:
a direct-forward mode, which is used to forward the primitive set of address and chip selection signals directly as the output set of address and chip selection signals to the memory device, and;
a row-address inversion mode, which is used to invert the row-address signal in the primitive set of address and chip selection signals to an inverted row-address signal.

6. The memory fault detection and isolation system of claim 5, wherein the decoding unit further includes:
a chip-slicing mode, which is used to slice the storage space of the memory device by simulation into a plurality of subregions; and wherein when the first chip-selection signal or the second chip-selection signal is enabled, it enables the output first chip-selection signal; and when the first chip-selection signal is enabled while the second chip-selection signal is disabled, it causes the most significant bit in the output row-address signal to be set to logic-LOW; and when the first chip-selection signal is disabled while the second chip-selection signal is enabled, it causes the most significant bit in the output row-address signal to be set to logic-HIGH.

7. The memory fault detection and isolation system of claim 5, wherein the decoding unit further includes:
a faulted-chip slicing mode, which is used to slice aside the faulted part of the memory device so as to isolate the faulted part; and wherein the most significant bit of the output row-address signal is fixedly set at either logic-HIGH or logic-LOW.

8. The memory fault detection and isolation system of claim 5, wherein the decoding unit further includes:
a chip-combining mode, which is used to combine two or more isolated faulted parts into a single chip by simulation; and wherein when the first chip-selection signal is enabled while the most significant bit of the row-address signal is logic-LOW, it causes the output first chip-selection signal to be enabled; and when the first chip-selection signal is enabled while the most significant bit of the row-address signal is logic-HIGH, it causes the second output chip-selection signal to be enabled.

9. The memory fault detection and isolation system of claim 5, wherein the decoding unit further includes:
a faulted-chip bank-address slicing mode, which is used to slice aside and isolate faulted parts of the memory device in groups; and wherein the most significant bit of the output bank-address signal is fixedly set to either logic-HIGH or logic-LOW.

10. The memory fault detection and isolation system of claim 5, wherein the decoding unit further includes:
a bank chip combining mode, which is used to combine the isolated faulted parts of the memory device into an integral chip; and wherein when the first chip-selection signal is enabled while the first bank-address signal and the second bank-address signal are at logic-LOW, it causes the output first chip-selection signal and the output bank-address signal to be set to logic-LOW; when the first chip-selection signal is enabled while the first bank-address signal is at logic-LOW and the second bank-address signal is at logic-HIGH, it causes the output first chip-selection signal to be enabled and the output bank-address signal to be set to logic-HIGH; when the first chip-selection signal is enabled while the first bank-address signal is at logic-HIGH and the second bank-address signal is at logic-LOW, it causes the second output chip-selection signal to be enabled and the output bank-address signal to be set to logic-LOW; and when the first chip-selection signal is enabled while the first bank-address signal is at logic-HIGH and the second bank-address signal is at logic-HIGH, it causes the second output chip-selection signal to be enabled and the output bank-address signal to be set to logic-HIGH.

11. The memory fault detection and isolation system of claim 5, wherein the decoding unit further includes:
a chip bank-address slicing mode, which is used to slice each of the isolated faulted parts of the memory device further into a plurality of subgroup chips; and wherein when the first bank-address signal and the second bank-address signal are both at logic-LOW, it causes the output bank-address signal to be set to logic-LOW and the most significant bit of the output row-address signal to be set to logic-LOW; when the first bank-address signal is at logic-LOW and the second bank-address signal is at logic-HIGH, it causes the output bank-address signal to be set to logic-LOW and the most significant bit of the output row-address signal to be set to logic-HIGH; when the first bank-address signal is at logic-HIGH and the second bank-address signal is at logic-LOW, it causes the output bank-address signal to be set to logic-HIGH and the most significant bit of the output row-address signal to be set to logic-LOW; and when the first bank-address signal is at logic-HIGH while the second bank-address signal is at logic-HIGH, it causes the output bank-address signal to be set to logic-HIGH and the most significant bit of the output row-address signal to be set to logic-HIGH.

12. The memory fault detection and isolation system of claim 5, wherein the mode-setting storage unit is an EEPROM unit.
